(19) United States
(12) Patent Application Publication
(10) Pub. No.: US 2025/0368863 A1
(43) Pub. Date: Dec. 4, 2025

(54) LOW-RESIDUE HIGH TEMPERATURE-RESISTANT DRY ADHESIVE AND METHODS OF USE

(71) Applicant: Shin-Etsu Chemical Co., Ltd., Tokyo (JP)

(72) Inventors: Burak AKSAK, Pittsburgh, PA (US); Elliot GEIKOWSKY, Pittsburgh, PA (US)

(21) Appl. No.: 19/236,987

(22) Filed: Jun. 13, 2025

Related U.S. Application Data
(63) Continuation of application No. PCT/US2023/085474, filed on Dec. 21, 2023.
(60) Provisional application No. 63/434,377, filed on Dec. 21, 2022.

(51) Int. Cl. C09J 7/38; C09J 5/06; H01L 21/683

(52) U.S. Cl. CPC C09J 7/38; C09J 5/06; C09J 2203/326; C09J 2203/37; C09J 2301/124; C09J 2301/202; C09J 2301/31; C09J 2483/00; H01L 21/6835

(57) ABSTRACT

A dry adhesive microfiber array comprising a plurality of fibers with tips adapted to contact a surface, where the dry adhesive is capable of adhering to the surface at elevated temperatures. The bonding strength of the dry adhesive remains constant or increases with increasing substrate/dry adhesive/carrier temperature. The dry adhesive can be debonded without leaving a residue on the surface of the substrate. In addition, the effect of temperature on bonding strength of the dry adhesive is reversible.

### CROSS-REFERENCE TO RELATED APPLICATIONS

This application is a continuation of International Application No. PCT/US2023/085474 filed on Dec. 21, 2023, which claims priority to U.S. Application No. 63/434,377 filed on Dec. 21, 2021, the contents of which are hereby incorporated by reference in their entirety.

### BACKGROUND

### 1. Technical Field

This invention relates to dry adhesives.

### 2. Related Art

The invention relates generally to dry adhesives. More specifically, the invention relates to dry adhesives comprising an array of micro- and/or nano-scale fiber arrays that can be used to temporarily secure silicon wafers, glass, metal, and other high temperature-resistant substrates to other substrates (called carriers) without damaging either substrate or leaving unwanted residue on either substrate.

Semiconductor and glass manufacturing involves several high temperature processing steps at high temperatures (above 230° C.). These processes can last for several minutes or more, even longer than an hour. Such processes include, but are not limited to solder reflow, tempering, lamination, layer deposition, and other high-temperature processes. During these processes, the substrate (glass/silicon/polysilicon/metal, etc.) is applied to a carrier via a removable adhesive, goes through one or more high temperature processes, and is then removed from the carrier. These processes are often automated and require high yield to be cost-effective, therefore upon removal of the substrate from the carrier at the conclusion of a high temperature process, the substrate will often automatically be transferred to another automated process (either at elevated temperature or not) and the carrier will have a new substrate applied to it so that the process can be repeated for a new substrate. During these processes, it is critical that the substrate stays securely attached to the carrier at high temperatures, and can be removed from the carrier without damaging either the carrier or the substrate, and with low residue left behind on the substrate.

Current solutions for high temperature bonding of silicon wafers to carriers often depend on the use of liquid adhesives which cross-link to form a strong attachment before high temperature processing. At the conclusion of the high temperature process, the liquid adhesive may be removed from the carrier using powerful solvents or chemical etching processes. These processes can be time consuming, expensive, can rely on materials which create safety or environmental concerns, and can result in reduced process yield. As such, there is a long-felt industry need for high temperature, low residue adhesives which can provide a reversible, repeatable bond and be removed without solvents or etching processes.

The industry standard for removable adhesive is the high temperature Kapton® tape, comprised of a polyamide carrier and a silicone pressure sensitive adhesive (PSA). While select PSAs can withstand temperatures above 230° C. for short periods of time, they are not stable at those temperatures for over an hour due to rapid oxidation and pyrolysis. Oxidation and pyrolysis lead to deterioration of the PSA layer and subsequent residue left behind on the substrate. Additionally, highly viscoelastic materials such as PSAs suffer from decreased adhesion with increasing temperature.

Therefore, it would be advantageous to develop a dry adhesive that overcomes these limitations associated with high temperatures by providing adhesion that does not decrease with temperature, where the adhesive does not degrade significantly at elevated temperatures over prolonged exposure times, allowing for residue-free removal from a substrate.

### GENERAL DISCLOSURE

One embodiment of the present invention is a dry adhesive having an array of fibers capable of adhering to either a smooth flat substrate or a patterned substrate, such as the surface of a silicon wafer. The dry adhesive, in one embodiment, comprises an array of micro- and/or nano-scale fibers extending from a backing, where the fibers have an enlarged, shaped tip. The adhesive is described as ‘dry’ because it does not rely on a pressure sensitive adhesives, liquids, or glues for adhesion. Rather, the structure of the fibers in the array are responsible for adhesion. When the tips make contact with the surface of the wafer, they provide an adhesion force. Removal can be accomplished by peeling the dry adhesive from the substrate or moving the substrate in a direction parallel to the surface of the dry adhesive. In addition, the dry adhesive can be produced from a material stable at high temperatures, such as liquid silicone rubbers (LSRs). As a result, the adhesive does not suffer from high degree of degradation at high temperatures, its adhesion increases with temperature, and it can be removed without leaving residue on the adhering surface. Because the dry adhesive is fabricated entirely of high-temperature resistant material, there is no need for a PSA layer, eliminating the instable element of the finished product.

The dry adhesive can be formed as a thin film, a tape, or fabricated directly onto the surface of the carrier. Debonding the dry adhesive does not require chemicals or complicated processing steps other than physical removal of the wafer from the carrier. Since the dry adhesive does not consist of complex multi-component liquid adhesives, there is significant reduction in the amount of residue left on the surface of the substrate after debonding, including at elevated temperatures.

### BRIEF DESCRIPTION OF THE DRAWINGS

FIGS. 1A-1B are images showing the structure of the dry adhesive, according to one embodiment.

FIG. 1C shows the dry adhesive with an object adhered to the fibers.

FIG. 2 is a graph showing adhesion force as a function of temperature.

FIG. 3 is a graph showing shear force as a function of temperature.

FIG. 4 is a graph showing shear force as a function of contact time and temperature.

FIG. 5 is a graph showing shear force as the temperature alternates from low to high.

FIG. 6 is a graph comparing the shear force of PSA to the dry adhesive as a function of temperature.

### DESCRIPTION OF EXEMPLARY EMBODIMENTS

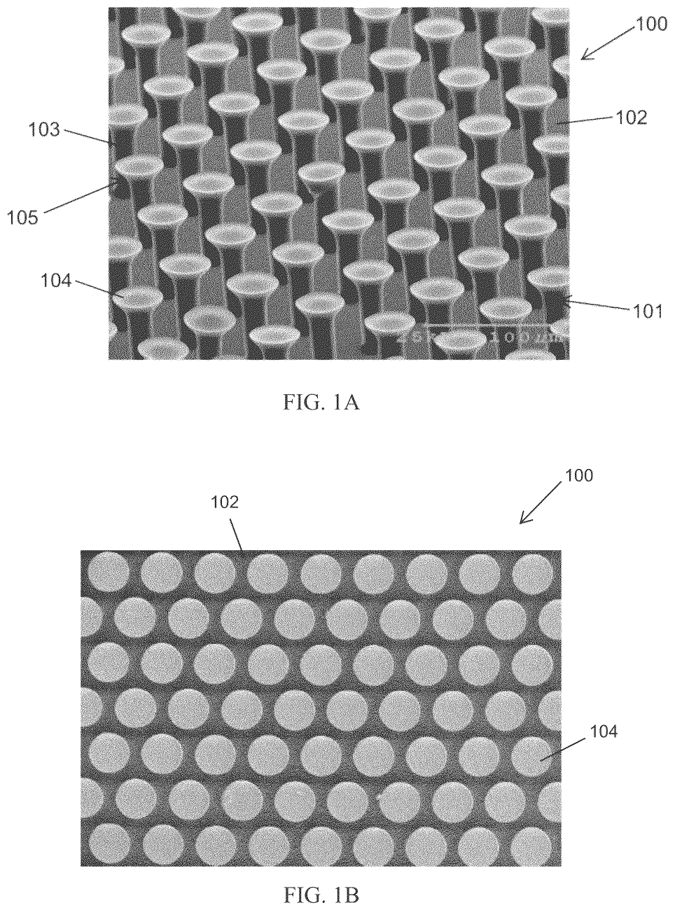

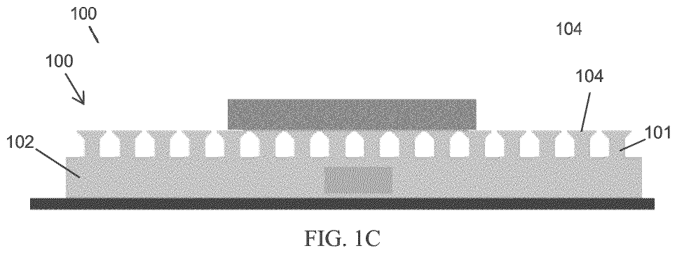

In one example embodiment, as shown in FIGS. 1A-1B, the dry adhesive microfiber array 100 comprises a plurality of fibers 101 attached to a backing layer, carrier, or substrate 102. In one embodiment, the fiber 101 attaches at a proximate end to the backing layer, carrier, or substrate 102 at a substantially perpendicular angle (see FIG. 1A). In this embodiment, each fiber includes stem 103 and a tip 104, which may be enlarged (i.e. the radius of the tip 104 is greater than the radius of the stem 103). In one embodiment, the tip 104 is a mushroom-shaped tip 104 with a flat surface at the distal end of the fiber 101. The stem 103 and tip 104 are symmetrical about symmetry axis, such that radius a of the stem 103 (up to the point of connection 105 with the tip 104) is constant along the length of stem 103. However, in alternative embodiments, the radius of the stem 103 can vary along its length, including one embodiment where the radius of the stem 103 near the backing layer 102 is enlarged. In this example embodiment, the tip 104 is also symmetrical and is fixed in radial direction to enable increased contact with a surface, such as a semiconductor device, a silicon wafer, chip, die, semiconductor package, or other similar device. A top view of the tip 104 is shown in FIG. 1B. In one embodiment, the surface of the tip 104 and the cross-section of the stem 103 are circular. In other embodiments, however, an oval or elliptical shape and/or cross-section may be used for either the stem 103 or the tip 104. The shape of the sides on the underside of the tip 104 is linear but, alternatively, can be convex or concave with respect to the stem axial direction and tip surface.

In an alternative embodiment, the dry adhesive 100 may comprise a film or tape having fibers 101 on opposing sides, similar to double-sided tape. In this configuration, the tape, or dry adhesive 100, can be placed on the carrier, with the semiconductor device then placed on top of the tape 100, as shown in FIG. 1C. During debonding, the manufacturer has the option to remove the carrier from the device or to remove the device from the carrier. For example, if a wafer will be transferred to a different carrier for a subsequent processing step, the wafer and tape 100 can be removed from the carrier and be placed on the surface of the different carrier. Because the dry adhesive fiber array 100 does not lose adhesion when removed, it will adhere to the different carrier. By leaving the dry adhesive 100 affixed to the wafer, the handling steps involving the device-side of the wafer is reduced.

During the bonding process, a plurality of fibers 101 of the dry adhesive 100 attaches, adheres, or otherwise bonds, as is known in the art, to the surface of the device. More specifically, the tips 104 of the fibers 101 contact the surface of the device and provide an adhesive force. The bonding strength of the dry adhesive 100 can be tailored to a particular processing step. The use of a lower bonding strength decreases the chances of damaging a device upon dry adhesive 100 removal. Bonding strength can be adjusted by varying the parameters of the fiber design, including fiber length, fiber radius, backing layer thickness, tip diameter, tip height, the angle between the surface of the tip and the side of the tip, fiber density, and material choice. In one example embodiment, the fiber 101 is constructed from liquid silicone rubber in a molding process known to those having skill in the art, where the liquid silicone rubber is poured into a mold and cured into a solid form. In this example embodiment, the dry adhesive 100 may have fibers 101 with a 4 μm stem radius, 8 μm tip radius, and 20 μm length. In other embodiments of the invention, the dry adhesive 100 may have fibers 101 with a stem radius between 5 μm and 100 μm, a tip radius between 6 μm and 200 μm, and a fiber length between 5 μm and 200 μm, for example. The liquid silicone rubber may be a platinum cure silicone rubber, such as Shinetsu KEG 2000-40, Shinetsu KE 1950-50, Elastosil LR 3043/50, or Elkem Silbione LSR 4340.

In other embodiments, the dry adhesive 100 is made from liquid silicone rubber, exhibiting very good chemical resistance to most acids, bases, inorganic chemicals, organic chemicals, and solvents. In alternative embodiments, the stem 103 of the fiber 101 can be made from a first material and the tip 104 constructed from a second material. For example, the stem 103 can be made from a high temperature silicone to maintain its tensile strength while the tip 104 is made from a typical silicone, which exhibits strong adhesion over a range of temperatures, as will be discussed below.

In certain example embodiments, the high temperature resistant dry adhesives 100 are constructed from arrays of micro- and/or nano-structures having enlarged tips 104 and/or enlarged stem bases 103, as discussed above. The enlarged tip 104 can include a mushroom shape, where the tip 104 has a thickness and has a greater radius than the stem 103. In other embodiments of the invention, adhesion-enhancing dry adhesives 100 may be constructed from high temperature-resistant resins from other patterned structures known to enhance or modify adhesion, including: solid prismatic shapes with uniform cross-section; prismatic shapes with non-uniform cross section; enlarged prism tip shape; spatula tip shape; mushroom tip shape, concave tip shape; micro-patterned features which recess into the part surface, and other similar shapes. In many of these examples, the shape of the fiber 101 and/or tip 104 enhances the surface area of contact between the dry adhesive 100 and the part to be adhered. Other fiber characteristics can also be varied to adjust bonding strength.

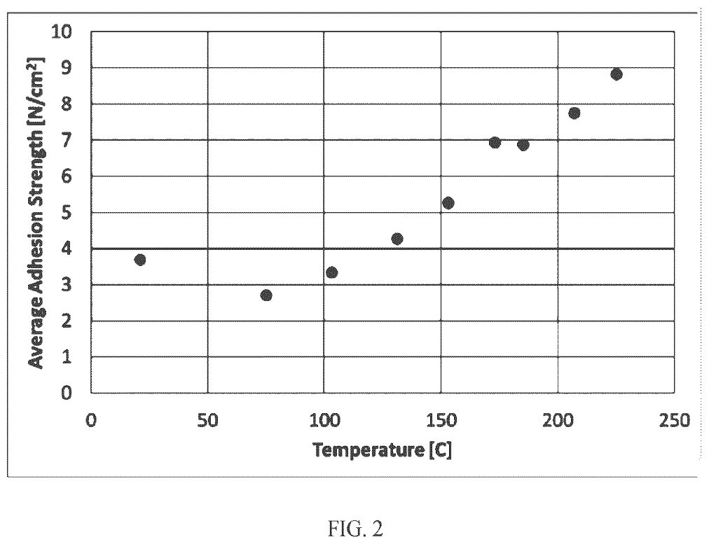

Temperature can also affect the adhesion properties of the dry adhesive 100. FIG. 2 shows the force of adhesion for a dry adhesive 100 at various temperatures ranging from 20° C. to 225° C. The y-axis of FIG. 2 shows the normal force in Newtons per square centimeters and the x-axis shows the surface temperature of the dry adhesive 100. FIG. 2 depicts a single measurement at each temperature. As shown in FIG. 2, the force of adhesion in normal direction, after showing a slight reduction at 70° C., increases with increasing temperature. Liquid adhesives and pressure sensitive adhesives typically exhibit an inverse relationship with temperature, unlike the results for the dry adhesive 100 shown in FIG. 2.

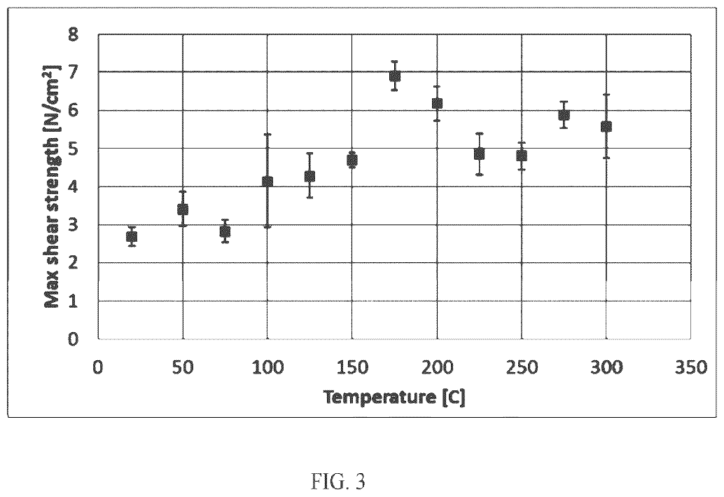

FIG. 3 show the shear force for a dry adhesive 100 at various temperatures ranging from 20° C. to 300° C. The y-axis of FIG. 3 shows the shear force in Newtons per square centimeters and the x-axis shows the surface temperature of the dry adhesive 100. FIG. 3 depicts the average of five measurements and standard deviation of those measurements at each temperature. As shown in FIG. 3, the shear force, like the force of adhesion in normal direction, shows a general trend of increase with increasing temperature.

In some instances, the increase in adhesion and shear of the fiber array 100 with increasing temperature is due to the formation of hydrogen bonds at the tip 104 with the substrate. Platinum cure silicones are known to produce hydroxyl groups at elevated temperatures. However, in the absence of a hydrophilic substrate in contact, the hydroxyl groups tend to migrate to the bulk of the silicone. When the fibers 101 are in contact with hydrophilic surfaces like glass, silicon, and other surfaces that could create hydrogen bonds, hydroxyl groups are generated and stay at the surface at higher rates with increased temperature. The increase in the number of hydroxyl groups lead to an increased number of hydrogen bonds, increasing adhesion. Once the surface is separated from the silicone microfibers and both the substrate and the microfiber array 100 are cooled down to room temperature, the hydroxyl groups disappear and the adhesion reverts back to its lower value at room temperature.

A typical pressure sensitive adhesive (PSA) is a viscoelastic substance owing its tack mainly to its viscous properties. As the temperature increases, the viscosity of PSA decreases, resulting in reduced normal, shear, and peel adhesion. For instance, 3M published the results of 180 degree-peel experiments for one of its high temperatures tapes, 3M Adhesive Transfer Tape 9082, as a function of temperature. It reported the 180 degree-peel at 72° F. to be approximately 5 lbs/inch, decreasing gradually at higher temperatures. The reported 180-degree peel result at a higher temperature is as low as approximately 2 lbs/inch, showing a significant reduction in adhesion. All four tested 3M high temperature PSAs showed a similar trend, exhibiting lower peel resistance with increasing temperature.

Soft materials, such as those used in the construction of the dry adhesive 100, are expected to perform poorly at high temperatures due to the temperature related degradation of material but primarily because of the reduction in the intermolecular attraction force due to high thermal fluctuations. The intermolecular attraction between surface molecules of contacting opposite surfaces is, in general, stronger the closer the molecules are to one another. At higher temperatures, the thermal fluctuations of the surface molecules result in a larger mean separation distance (compared to absolute zero where the surface molecules are immobile), and thus result in a weaker bond between the opposing surfaces due to larger average separation. However, the structure of the dry adhesive 100 permits strong adhesion at elevated temperatures.

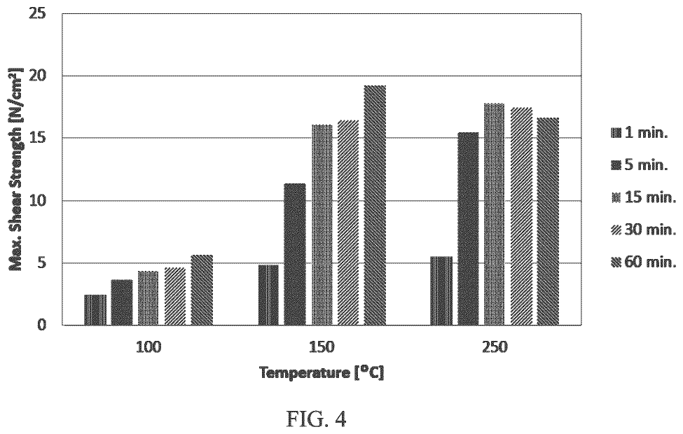

FIG. 4 shows the effect of contact time between the dry adhesive 100 and a substrate on shear force as a function of temperature. The y-axis of FIG. 4 shows the shear force in Newtons per square centimeters and the x-axis shows the surface temperature of the dry adhesive 100, with each column representing a contact time at the elevated temperature ranging from 1 minute to 60 minutes. Data indicates that the rate of change of shear of the dry adhesive 100 is higher with temperatures after prolonged contact. Additionally, for all the tested temperatures, shear increases with contact time. In all test cases, the dry adhesive 100 sample was able to be removed from the heated substrate without any visible damage to the substrate or the dry adhesive 100, and without any visible residue left behind on the substrate itself when the dry adhesive 100 was returned to ambient temperature. Additionally, adhesion of dry adhesive 100 is not only variable with temperature but it also reversible. This effect allows the dry adhesive 100 to exhibit high adhesion at high temperatures, while still allowing removal without residue. As a result, the dry adhesive 100 can be cooled and returned to its cool-temperature adhesion level, allowing easy removal.

A typical dry adhesive is constructed from soft elastomers. As such, their adhesion performance is expected to exhibit similar behavior to soft materials, that is, its adhesion is expected to decrease with increasing temperature, as in soft materials in general, because of the reduction in intermolecular attractive forces due to thermal fluctuations. In contrast, the dry adhesive 100 of the present disclosure exhibits strong adhesion even when constructed from soft elastomers.

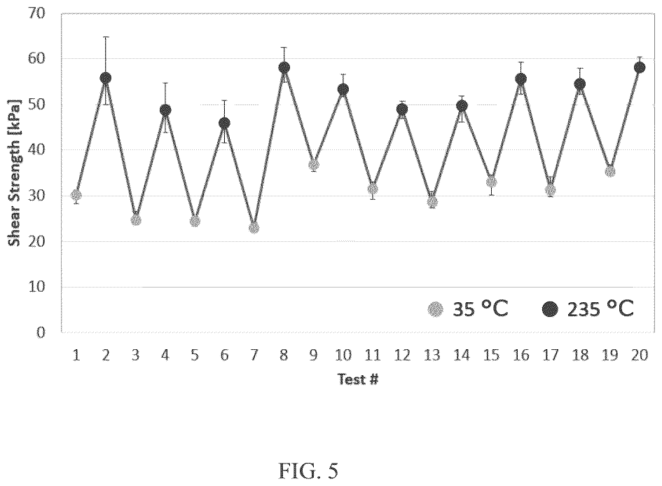

FIG. 5 shows the shear force in Newtons per square centimeters of the dry adhesive 100 when the temperature is cycled between 35° C. and 235° C. FIG. 5 depicts the average of five measurements and standard deviation of those measurements at each temperature. The relative increase of shear at the higher temperature compared to the lower temperature indicates that the dry adhesive is a reusable and reversible adhesive. This data also suggests that there is minimal degradation to the material due to exposure to high temperatures or the debonding process. This observation is confirmed through visual inspection of the dry adhesive 100 before and after being subjected to the temperature cycling. No broken fibers 101 can be observed, nor is there any discoloration to the dry adhesive material, nor any visible residue left behind on the test surface.

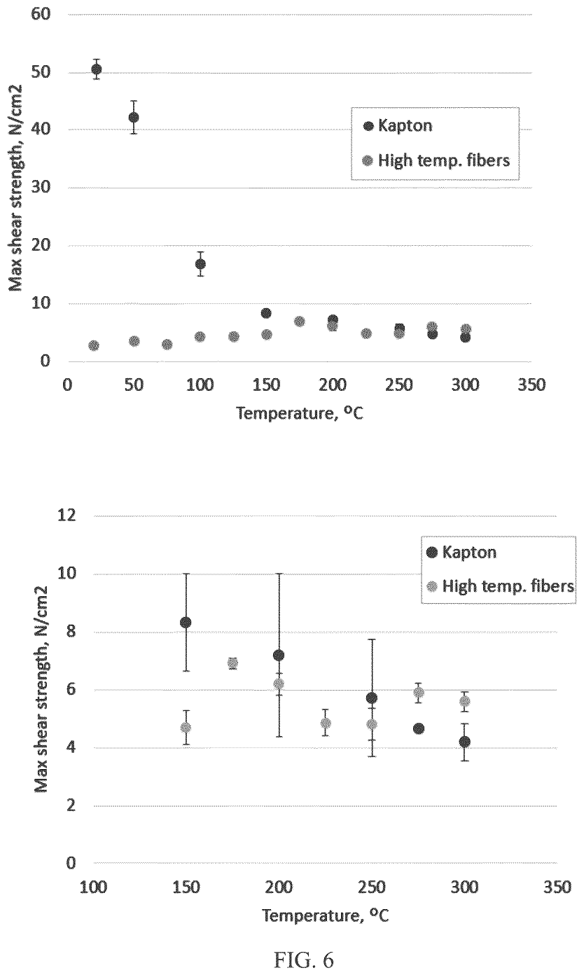

FIG. 6 shows the shear force in Newtons per square centimeters of the dry adhesive 100 compared with a silicone-based, high-temperature pressure sensitive tape (Kapton tape) as a function of temperature, decreasing from just above 8 N/cm2 at 150° C. to about 4 N/cm2 at 300° C. In contrast, the dry adhesive 100 has an adhesion of about 4 N/cm2 at 150° C. to about 6 N/cm2 at 300° C. FIG. 6 depicts the average of five measurements and standard deviation of those measurements at each temperature. Measurement results indicate that Kapton tape loses shear performance with temperature, and after 250° C., the dry adhesive 100 provides higher shear force.

Increasing shear and normal forces with temperature can be utilized to minimize the possibility of adhesion loss between the substrate and the carrier at elevated temperatures.

The dry adhesive 100 provides unique advantages over existing mechanisms for bonding and debonding. For example, the dry adhesive 100 of the present invention does not lose adhesion at elevated temperatures ensuring the secure attachment of the substrate to a carrier. This is contrary to PSAs where elevated temperatures significantly reduce adhesion. Additionally, the dry adhesive 100 does not suffer from degradation because it is made from high temperature stable silicones. Thus, it can be removed from a substrate residue free even after prolonged exposure to high temperatures, increasing process throughput, eliminate extra cleaning steps, and enable a high yield. Furthermore, it can be re-used multiple times for multiple heating cycles without loss of performance, minimizing the amount of material required to operate a process over extended cycles, saving both time and providing a more sustainable solution than single-use adhesives.

While this invention describes an embodiment of a high temperature-resistant dry adhesive produced using liquid silicone rubbers, other embodiments of the invention may be produced from other resins known to those skilled in the art to be able to be formed into different micro- and/or nano-scale structures and be resistant to high temperatures. These include, but are not limited to: compression molded silicones, cast silicones, fluorinated elastomeric compounds, perfluorinated elastomeric compounds, chlorosulphonated polyethene rubbers, hydrogenated acrylonitrile-butadiene rubbers, ethylene-propylene-diene monomers, and polytetrafluoroethylenes.

The features disclosed in the foregoing description, or the following claims, or the accompanying drawings, expressed in their specific forms or in terms of a means for performing the disclosed function, or a method or process for attaining the disclosed result, as appropriate, may, separately, or in any combination of such features, be utilized for realizing the invention in diverse forms thereof. In particular, one or more features in any of the embodiments described herein may be combined with one or more features from any other embodiments described herein.

Protection may also be sought for any features disclosed in any one or more published documents referred to and/or incorporated by reference in combination with the present disclosure.

What is claimed is:

1. A dry adhesive comprising:
a plurality of fibers comprising a stem and a tip disposed on a distal end of the fiber;
a backing layer, wherein a proximate end of the fiber is attached to a first surface of the backing layer,
wherein the dry adhesive maintains adhesion across a range of temperatures.

2. The dry adhesive of claim 1, wherein the range of temperatures includes temperatures above 230° C.

3. The dry adhesive of claim 1, wherein the plurality of fibers comprises a silicone rubber.

4. The dry adhesive of claim 1, further comprising:
additional fibers disposed on a second surface of the backing layer, wherein the second surface is opposite to the first surface.

5. The dry adhesive of claim 1, wherein the stems comprise a first polymer and the tips comprise a second polymer.

6. The dry adhesive of claim 5, wherein the first polymer comprises a high temperature silicone.

7. A method of adhering a device to a carrier comprising:
providing a dry adhesive comprising a plurality of fibers comprising a stem and a tip, wherein the tip is disposed on a distal end of the fiber;
contacting the dry adhesive to a device; and
subjecting the device and dry adhesive to a maximum temperature of at least 225° C.,
wherein a force of adhesion between the dry adhesive and the device remains constant or increases when subjected to the maximum temperature.

8. The method of claim 7, further comprising:
cooling the device and dry adhesive to a temperature below the maximum temperature; and
removing the dry adhesive from the device.

9. The method of claim 7, wherein the device comprises a silicon wafer, a silicon carbide wafer, a semiconductor device, glass, or a computer processor.

10. The method of claim 7, wherein the dry adhesive and device are subjected to the maximum temperature for a period of time of at least 1 minute.

11. The method of claim 7, wherein the dry adhesive and device are subjected to the maximum temperature for a period of time of at least 60 minutes.

12. The method of claim 7, further comprising cycling the temperature between a minimum temperature and the maximum temperature.

13. The method of claim 7, wherein the force of adhesion is at least 5 N/cm2 at a temperature of 250° C.

14. A method of adhering a hydrophilic material to a substrate comprising:
providing a dry adhesive on a surface of the substrate, the dry adhesive comprising:
a plurality of fibers comprising a stem and a tip disposed on a distal end of the fiber; and
a backing layer, wherein a proximate end of the fiber is attached to a first surface of the backing layer;
affixing the hydrophilic material to the dry adhesive at a first temperature; and
heating the dry adhesive to a second temperature.

15. The method of claim 14, wherein the second temperature is at least 230 degrees Celsius.

16. The method of claim 14, further comprising:
cooling the dry adhesive to a temperature below the second temperature; and
removing the hydrophilic material from the dry adhesive.

17. The method of claim 14, wherein a hydroxyl group is present on the tip at the second temperature.
